(19) United States
(12) Patent Application Publication
(10) Pub. No.: US 2023/0236322 A1
(43) Pub. Date: Jul. 27, 2023

(54) IMAGE SENSOR AND DETECTION SYSTEM USING SAME

(71) Applicant: Ningbo ABAX Sensing Electronic Technology Co., Ltd., Ningbo City (CN)

(72) Inventor: Shuyu LEI, Ningbo City, Zhejiang Province (CN)

(73) Assignee: Ningbo ABAX Sensing Electronic Technology Co., Ltd., Ningbo City (CN)

(21) Appl. No.: 18/001,737

(22) PCT Filed: Jun. 15, 2021
(86) PCT No.: PCT/CN2021/099952

§ 371 Date: Dec. 14, 2022

(30) Foreign Application Priority Data
Jun. 28, 2020 (CN) 202010597663.1
Jun. 28, 2020 (CN) 202010598950.4
Jun. 28, 2020 (CN) 202010599650.8

(51) Int. Cl. G01S 17/894; G01S 7/481; H04N 25/78; H01L 27/146; H04N 25/705

(52) U.S. Cl. CPC G01S 17/894; G01S 7/4816; H01L 27/14634; H04N 25/78; H04N 25/705

(57) ABSTRACT

Provided are an image sensor and a detection system using same, which belong to the field of semiconductor image sensors. The image sensor includes: a first substrate, wherein the first substrate at least includes a photoelectric unit for photoelectric conversion, and N signal transmission channels which are connected to the photoelectric unit, with N being greater than or equal to 1; and a second substrate, which includes N second charge storage units which correspond to the N transmission channels. The transmission channels receive control signals, electrically communicate the photoelectric unit and the second charge storage units, and transfer at least some photo-induced electrons, which are generated in the photoelectric unit, to the second charge storage units. The effect of miniaturization and high integration design of pixels is ensured by means of stacking two substrates; and by means of further providing charge storage units on both of the two substrates, the area of the peripheral region of the pixels can be used, the effect of a higher charge storage amount can be achieved, and the effects such as measurement accuracy can be ensured.

The present application claims priorities to Chinese Patent Applications No. CN202010598950.4 titled “THREE-DIMENSIONAL IMAGE SENSOR”, No. CN202010599650.8 titled “DETECTION DEIVICE”, and No. CN202010597663.1 titled “IMAGE SENSOR AND ELECTRICAL DEVICE”, filed on Jun. 29, 2020 with the Chinese Patent Office, all of which are incorporated herein by reference in their entireties.

### FIELD

The present disclosure relates to the technical field of semiconductor image sensors, and in particular to an image sensor and a detection system including the image sensor.

### BACKGROUND

In the field of the detection technology, more and more technologies are proposed. In order to ensure efficient and fast detection for target information in applications such as image or distance measurement, the efficiency of acquiring the detection information is paid more and more attention. The absorption rate of the pixel unit in the detector for the light directly affects the quality of the image obtained by the detector or the accuracy of the data in the distance measurement. This type of detector generally includes a photoelectric conversion elements used to convert the incident light into an electrical signal. The photoelectric conversion elements may be roughly classified into two types, i.e., charge-coupled devices (CCD) and complementary metal-oxide-semiconductors (CMOS). The CMOS is used to convert charges into a voltage per unit pixel and output the signal from the signal line by switching operation. The difficulty of the circuit to be arranged in the pixel is increased as the size of the device becomes small.

With the development of the detection technology, the laser distance measurement as an active detection type of detection system, is mainly implemented by a Time of flight (TOF) distance measurement method. The principle of the TOF method is described as follows. A light pulse is continuously emitted to a target, and a light returned from the target is received by a sensor, and the distance to the target is obtained by detecting the flight (round-trip) time of the light pulse. The distance information may be used to form three-dimensional image information with depth information. The TOF method has been widely used in more and more applications, such as automatic driving, phone three-dimensional photography and other applications. The Direct Time of Flight (DTOF) is a kind of the TOF. In the DTOF technology, the target distance is directly acquired by calculating the emission time and the reception time of the light pulse, having the advantages of simple principle, high signal-to-noise ratio, high sensitivity and accuracy, and thus has attracted more and more attention. Similarly, a high-precision and high-sensitivity distance detection can be achieved with the ITOF solution.

The detection sensor generally performs the distance detection by a pixel array, and each unit in the array is required to transmit the charge information converted by the light. Therefore, for the ITOF technology, a phase delay solution is generally used, which requires multiple groups of circuit devices. Further, for the DTOF technology, the data volume is large, and a certain amount of intra-pixel circuits are required, while the size of the whole device is required as small as possible in order to achieve the high distance measurement efficiency and accuracy. In order to solve this problem, the pixel size is required to be reduced to improve the integration density and efficiency of the detection sensor. In addition, in the distance measurement equation, several different phase information of the reflected signal is generally involved, i.e., the distance to the target object is determined based on the phase information. The phase information is generally first converted into an electrical signal by the photoelectric conversion device in the sensor, and the electrical signal needs to be stored in the charge storage unit. Different from the image sensors not for the distance measurement, the charge storage device is required to have a large capacity. However, in the sensor, due to the limited layout area of the chip, too many charge storage devices occupy too much of the chip area, resulting in a small remaining area and a small circuit scale.

### SUMMARY

An object of the present disclosure is to provide an image sensor and a detection system including the image sensor, which solves special requirements of integration density and efficiency in chip miniaturization, and further solves a contradiction between a storage capacity of a charge storage unit and an area of a pixel photoelectric unit in detection, especially in high-precision distance detection.

Embodiments of the present disclosure are provided.

In an aspect, an image sensor is provided according to an embodiment of the present disclosure. The image sensor includes: a first substrate and a second substrate. The first substrate includes at least a photoelectric unit for photoelectric conversion. N signal transmission paths are connected to the photoelectric unit, where N is greater than or equal to 1. The second substrate includes N second charge storage units respectively corresponding to the N transmission paths. The transmission paths are used to: receive control signals, electrically connect the photoelectric unit to the second charge storage units, and transfer at least part of photogenerated electrons generated in the photoelectric unit to the second charge storage units.

Optionally, the first substrate further includes N first charge storage units respectively corresponding to the N signal transmission paths. The transmission paths are used to: receive control signals and transfer at least part of the photogenerated electrons generated in the photoelectric unit to the first charge storage units and the second charge storage units. The second substrate further includes a processing circuit configured to process the photogenerated electrons stored in the first charge storage units and the second charge units.

Optionally, the first substrate further includes N transmission path control portions connected to the photoelectric unit to form an upstream pixel region. The second substrate further includes a downstream pixel region corresponding to the upstream pixel region. The upstream pixel is directly or indirectly connected to the N charge storage units of the downstream pixel via N bonding conductors respectively corresponding to the N signal transmission paths. The photogenerated electrons generated by the photoelectric units are at least partially transferred to the charge storage units.

Optionally, the number N of the signal transmission paths is two, the first substrate is connected to the second substrate by two bonding conductors, and the two charge storage units receive at least part of the photogenerated charges generated by the photoelectric unit via the two bonding conductors.

Optionally, the first substrate and the second substrate have different thicknesses.

Optionally, the first substrate and the second substrate are made of different materials and/or by different processes.

Optionally, the first transmission paths and the second transmission paths are formed by transistor structures and are electrically connectable to the first charge storage units and the second storage units in a time division manner so that the photogenerated electrons generated by the photoelectric unit are at least partially transferred to the first charge storage units or the second charge storage units.

Optionally, in a case that the number N of the transmission paths is greater than or equal to two, a space between centers of any two of the bonding conductors ranges from 2 µm to 6 µm.

Optionally, the second substrate further includes N transfer transistors respectively corresponding to the N signal transmission paths. The transfer transistors are arranged between the bonding conductors and the charge storage units.

Optionally, the second substrate further includes N source followers, and the N source followers are respectively connected to the N charge storage units.

Optionally, the second substrate further includes N row selection transistors respectively connected to the N source followers.

Optionally, the image sensor further includes a pixel array in which multiple pixels are arranged in rows in a first direction and in columns in a second direction. Each of the multiple pixels is formed by connecting the upstream pixel region to the downstream pixel region via multiple bonding conductors.

Optionally, a first pixel portion including at least the photoelectric unit of the upstream pixel region is provided on the first substrate. The second substrate includes a second pixel portion corresponding to the first pixel portion and is spaced apart from the first substrate in a vertical direction. The second pixel portion includes at least the second charge storage units.

Optionally, a horizontal section of the first pixel portion and a horizontal section of the second pixel portion are rectangular and overlap each other in the vertical direction.

Optionally, a storage capacity of the second charge storage unit is greater than a storage capacity of the first charge storage unit.

Optionally, the processing circuit includes:
a reset device configured to reset the second charge storage unit; and
a readout device configured to process and read out the photogenerated electrons in the charge storage unit.

Optionally, the number N of the signal transmission paths is two, and the first substrate includes two first charge storage units corresponding to the number of the signal transmission paths.

In a second aspect, there is further provided a detection system for performing detection by the image sensor as described in the first aspect in the present disclosure. The detection system includes: a light source and an image sensor. The light source is configured to emit a light signal to a target object. The image sensor is configured to receive the light signal reflected from the target object and generate an electrical signal. The image sensor includes: a first substrate and a second substrate. The first substrate includes at least a photoelectric unit for photoelectric conversion. N signal transmission paths are connected to the photoelectric unit, where N is greater than or equal to 1. The second substrate includes N second charge storage units respectively corresponding to the N transmission paths. The transmission paths are used to: receive control signals, electrically connect the photoelectric unit to the second charge storage units, and transfer at least part of photogenerated electrons generated in the photoelectric unit to the second charge storage units.

Optionally, the first substrate further includes N first charge storage units respectively corresponding to the N signal transmission paths. The transmission paths are used to: receive control signals and transfer at least part of the photogenerated electrons generated in the photoelectric unit to the first charge storage units and the second charge storage units. The second substrate further includes a processing circuit configured to process the photogenerated electrons stored in the first charge storage units and the second charge units.

Optionally, a storage capacity of the second charge storage unit is greater than a storage capacity of the first charge storage unit.

The present disclosure has the following beneficial effects. The image sensor includes: a first substrate and a second substrate. The first substrate includes at least a photoelectric unit for photoelectric conversion. N signal transmission paths are connected to the photoelectric unit, where N is greater than or equal to 1. The second substrate includes N second charge storage units respectively corresponding to the N transmission paths. The transmission paths are used to: receive control signals, electrically connect the photoelectric unit to the second charge storage units, and transfer at least part of photogenerated electrons generated in the photoelectric unit to the second charge storage units. The two substrates are stacked to form a detector array, and different parts of a pixel unit are arranged on different substrates to form an overall pixel unit, achieving a relative high integration level. Further, the thicknesses of the two substrates are different, for example, the thickness of the second substrate is greater than the thickness of the first substrate. The first substrate is designed in accordance with the optimal absorption depth of the laser light for the infrared type of detection. The thickness of the epitaxial layer in the first substrate may be designed to be more than 20 µm. The second substrate may be designed in accordance with the strength requirements of the whole array module, to ensure the higher integration level of pixel units and the safety and reliability of the whole device. Furthermore, the materials and/or manufacturing processes of the two substrates are different, for example, the first substrate may be made of a SiGe material, and the second substrate may be made of a silicon material. Further, the manufacturing processes of the two substrates are different, for example, the first substrate is set as an N-type epitaxial structure, and the second substrate is set as a P-type epitaxial structure. In this way, a fully depleted type region can be formed in the first substrate, improving the conversion efficiency of the photogenerated charge. Further, by the P-type epitaxial doping layer of the second substrate, the complex circuit in the pixel, especially for the ranging requirements, can contain more transistors for transfer, modulation, or the like, where such transistors are mostly NMOS transistors. By the process differential design of the two substrates, the higher integration requirements for the pixel size reduction and the overall device size reduction can be met, ensuring the reliability and efficiency of the whole device at a higher integration level and smaller size. Further, the first substrate further includes the N first charge storage units respectively corresponding to the N signal transmission paths. The transmission paths receive control signals and transfer at least part of the photogenerated electrons generated in the photoelectric unit to the first charge storage units and the second charge storage units. The second substrate further includes the processing circuit. The processing circuit is used to process the photogenerated electrons stored in the first charge storage units and the second charge storage units. The two substrates are both provided with charge storage units, which increases the remaining circuit area of the sensor to a certain extent, improves the scale of the circuit, further saves the cost of the substrate, achieves the storage for more photogenerated charges, and achieves the accurate acquisition for a detection result.

### BRIEF DESCRIPTION OF THE DRAWINGS

In order to illustrate technical solutions of embodiments of the present disclosure more clearly, the drawings used for the embodiments are briefly introduced in the following. It should be understood that the drawings show only some embodiments of the present disclosure, and should not be regarded as a limitation of the scope. Other drawings may be obtained by those skilled in the art from these drawings without any creative work.

FIG. 1 is a schematic diagram of an ITOF distance measurement system according to an embodiment of the present disclosure;

FIG. 2 is a schematic diagram showing modules of a pixel unit in an image sensor according to an embodiment of the present disclosure;

FIG. 3 is a schematic diagram showing a pixel circuit and corresponding control timing according to an embodiment of the present disclosure;

FIG. 4 is a schematic diagram showing a pixel circuit and corresponding control timing according to another embodiment of the present disclosure;

FIG. 5 is a schematic diagram showing a substrate arrangement of the image sensor according to the embodiment of the present disclosure;

FIG. 6 is a schematic diagram showing a module layout of the image sensor according to the embodiment of the present disclosure;

FIG. 7 is a perspective schematic view of the image sensor according to the embodiment of the present disclosure;

FIG. 8 is a schematic diagram showing a layout of the image sensor according to the embodiment of the present disclosure;

FIG. 9 is a schematic structural diagram showing a substrate connection portion of the image sensor according to the embodiment of the present disclosure;

FIG. 10 is a schematic diagram showing a conducting portion between a driving portion of the pixel circuit and a transmission path of a first substrate according to the embodiment of the present disclosure;

FIG. 11 is a schematic diagram showing a sensor array formed by multiple pixels according to an embodiment of the present disclosure;

FIG. 12 is a schematic diagram showing an equivalent circuit of an example pixel of a pixel array according to an embodiment of the present disclosure; and

FIG. 13 is a schematic diagram showing an equivalent circuit of an example pixel of a pixel array according to another embodiment of the present disclosure.

### DETAILED DESCRIPTION OF EMBODIMENTS

In order to make objects, technical solutions and advantages of the embodiments of the present disclosure clearer, the technical solutions in the embodiments of the present disclosure are clearly and completely described below with reference to the drawings in the embodiments of the present disclosure. Apparently, the described embodiments are some but not all embodiments of the present disclosure. Components of the embodiments generally described and illustrated in the drawings herein may be arranged and designed in a variety of different configurations.

Therefore, the following detailed description for the embodiments of the present disclosure provided in the drawings is not intended to limit the scope of the present disclosure as claimed, but is merely representative of selected embodiments of the present disclosure. Based on the embodiments in the present disclosure, all other embodiments obtained by those of ordinary skill in the art without creative work shall fall in the protection scope of the present disclosure.

It should be noted that, similar numerals and letters refer to similar items in the following drawings. Therefore, if an item is defined in a drawing, the item is not required to be further defined and explained in subsequent drawings.

It should be noted that, relational terms such as “first” and “second” herein are only used to distinguish one entity or operation from another entity or operation, and do not necessarily require or imply there is such actual relationship or sequence between these entities or operations. Moreover, terms “comprising”, “including” or any other variations thereof are intended to encompass a non-exclusive inclusion, such that a process, a method, an article or a device including a series of elements includes not only those elements, but also includes other elements that are not explicitly listed or inherent to such the process, method, article or device. Without further limitation, an element defined by a phrase “including a...” does not preclude the presence of additional identical elements in a process, method, article or device including the element.

In recent years, research on 3D imaging systems has made great strides in order for autonomous driving to be applied in daily life. There are several requirements for the imaging system in autonomous driving: resistance to large background light (the strongest sunlight is up to 100klux), high distance measurement accuracy and fast distance measurement. Therefore, a pixel circuit in the image sensor by which the waste of the area in the pixel can be reduced and a part of calculation can be completed during the operation of the circuit is needed to make the received signal more comprehensive, thereby improving the distance measurement accuracy, reducing the amount of subsequent data processing, saving data processing time, and quickly obtaining the distance to the object. Further, in other scenarios, a large storage capacity is required to meet more accurate detection requirements, and further to accommodate the miniaturization and high integration requirements of image sensors (including two-dimensional image sensors and three-dimensional image sensors).

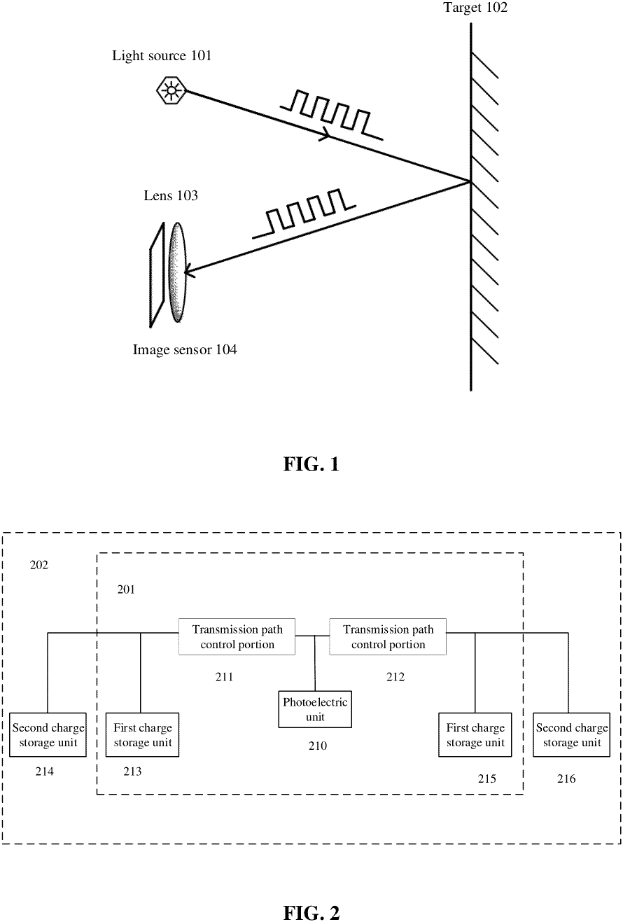

FIG. 1 is a schematic diagram showing a general TOF distance measurement principle, in which a flight time between a sensor and a to-be-measured object is acquired by a phase difference between an emission light signal and an echo signal, to further obtain distance information. As shown in FIG. 1, an emission light signal is emitted from a light source 101. The emission light signal may be a laser pulse signal modulated by a pseudo-random sequence or an unmodulated laser pulse signal. The emission light signal is reflected by an object 102 and is focused on pixels of an image sensor 104 by a lens 103. A signal received by the image sensor includes an echo signal and a background light signal or only includes the background light signal, where it is assumed that the background light signal is uniform in a time period. A pixel circuit in the image sensor 104 is used to perform signal cancellation or signal extraction on the received signal, to remove the background light signal and obtain a pure echo signal. Further, a phase difference of the echo signal in the returned light relative to the emission light signal is detected by each pixel, to determine a distance to a surrounding target. In the ITOF distance measurement, the image sensor 104 is required to receive the echo signal and perform phase modulation and processing on the signal, and perform photoelectric conversion on the processed signal, and further store and process the generated electrical signal. Therefore, the 3D image sensors are required to store more electrical charges compared with traditional 2D image sensors, and thus the electrical charge storage unit is required to have a more capacity.

An image sensor 200 is provided in the present disclosure, which is described below with reference to FIG. 2. The image sensor includes: a first substrate 201 and a second substrate 202. The first substrate 201 includes a pixel array. The pixel array includes pixel units. The pixel unit includes a photoelectric unit 210, a transmission path control portion 211 and a transmission path control portion 212, and a first charge storage unit 213 and a first charge storage unit 215. The second substrate 202 includes a second charge storage unit 214 and a second charge storage unit 215, and remaining processing circuits (which are not shown in the drawings). The remaining circuits may include a processing circuit, which may be used to process photogenerated electrons stored in the first charge storage unit 213, the second charge storage unit 214, the first charge storage unit 215 and the second charge storage unit 216. The photoelectric unit 210 is used to receive a light signal and generate photogenerated electrons. The transmission path control portion 211 and the transmission path control portion 212 are used to control the transmission of the photogenerated electrons generated in the photoelectric unit 210. The first charge storage unit 213, the second charge storage unit 214, the first charge storage unit 215 and the second charge storage unit 216 are used to store the photogenerated electrons that are generated by the photoelectric conversion of the photoelectric unit 210 and transmitted by the transmission path control portion 211 and the transmission path control portion 212. That is, in a case that the transmission path control portion 211 is opened, charges (the photogenerated electrons) in the photoelectric unit 210 are transferred to the first charge storage unit 213 and the second charge storage unit 214 via the transmission path control portion 211. Accordingly, in a case that the transmission path control portion 212 is opened, the charges in the transmission path control portion 210 are transferred to the first charge storage unit 215 and the second charge storage unit 216 via the transmission path control portion 212. With respect to the ITOF technology, the transmission path control portion 211 and the transmission path control portion 212 respectively transmit photogenerated electrons in different phases. For example, the transmission path control portion 211 may transmit photogenerated electrons in a phase of 0°, and the transmission path control portion 212 may transmit photogenerated electrons in a phase of 180°. Alternatively, the transmission path control portion 211 may transmit photogenerated electrons in a phase of 90°, and the transmission path control portion 212 may transmit photogenerated electrons in a phase of 270°. It can be seen that, the first charge storage unit 213 and the second charge storage unit 214 together store the photogenerated electrons transmitted by the transmission path control portion 211, and the first charge storage unit 215 and the second charge storage unit 216 together store the photogenerated electrons transmitted by the transmission path control portion 212. The first charge storage unit 213 and the second charge storage unit 214 are respectively arranged on the first substrate 201 and the second substrate 202. In this way, the first substrate and the second substrate together provide a charge storage unit for storing charges, avoiding a situation where the charge storage unit occupies a large amount of substrate area when being arranged on only the first substrate, which leads to a reduction in the area available for other circuits. In other words, by providing the charge storage unit on both substrates, the capacity of the charge storage unit can be increased, and thus the dynamic range of the image sensor can be improved.

In an embodiment, the storage capacity of the second charge storage unit 214 is greater than the storage capacity of the first charge storage unit 213, and the storage capacity of the second charge storage unit 216 is greater than the storage capacity of the first charge storage unit 215. In this way, the area occupied by the first charge storage unit 213 and the first charge storage unit 215 on the first substrate 201 can be further reduced, so that more pixel units can be arranged on the first substrate 201, thereby increasing the resolution and the dynamic range of the image processor.

In another embodiment, the first substrate 201 and the second substrate 202 are distributed in a vertical direction, the first substrate 201 and the second substrate 202 are connected via a bonding conductor (which is not shown in the drawings), the charge storage unit 213 and the charge storage unit 214 are electrically connected via the bonding conductor, and the charge storage unit 2,5 and the charge storage unit 216 are electrically connected via the bonding conductor.

In another embodiment, the processing circuit includes a reset device and a readout device. The reset device (which is not shown in the drawings) is used to reset the first charge storage unit 213, the second charge storage unit 214, the first charge storage unit 215, and the second charge storage unit 216. The readout device (which is not shown in the drawings) is used to process and read out the photogenerated electrons in the first charge storage unit 213, the second charge storage unit 214, the first charge storage unit 215, and the second charge storage unit 216. A case that the pixel unit is set to have a 2-Tap structure and there are two transmission paths connected to the photoelectric unit is schematically illustrated in the above. In the above, the number N of the transmission paths is two. In practice, the pixel may be set to contain a sub-pixel structure. For example, two or more sub photodiode structures are formed in each pixel region by the doping process, so that the number N of the transmission paths in the pixel structure may be set as 4 or the like, which is not limited herein. In such a structure, the image sensor can have a higher frame rate. For example, all the information of the four phases are obtained by the exposure for once, so that the distance calculation result can be rapidly outputted. Further, in the case that the number N of the transmission paths is four, four first charge storage units and four second charge storage units are correspondingly provided, to match the technical effect of higher frame rate and more accurate detection.

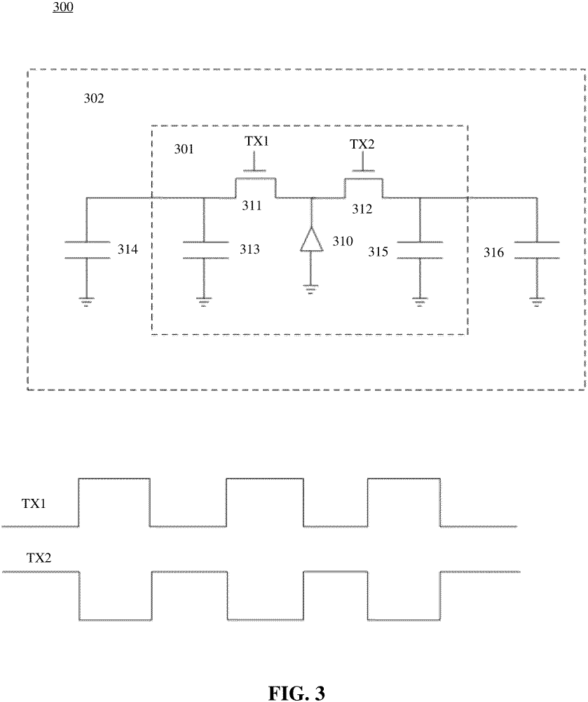

An image sensor provided in an embodiment of the present disclosure is described in detail with reference to FIG. 3, in which the photoelectric unit is a photodiode, the transmission path control portion is a transmission transistor, and the charge storage unit is a capacitor (including a MOS transistor capacitor, or the like). The image sensor 300 includes a first substrate 301 and a second substrate 302. The substrate 301 includes a pixel array including pixel units. The pixel unit includes: a photodiode 310, a transmission transistor 311, a transmission transistor 312, a capacitor 313 and a capacitor 315. The substrate 302 includes a capacitor 314, a capacitor 316, and a processing circuit (which is not shown in the drawings). The processing circuit is used to process the photogenerated electrons stored in the capacitor 313, the capacitor 314, the capacitor 315, and the capacitor 316.

The image sensor 300 operates as follows.

The photodiode 310 receives the light signal and generates photogenerated electrons. The transmission transistor 311 and the transmission transistor 312 control the transmission of the photogenerated electrons generated in the photodiode 310 via TX1 and TX2, respectively, where timings of TX1 and TX2 are as shown in FIG. 3. The two transmission transistors are alternately opened to transfer the photogenerated electrons in the photodiode 310. Specifically, the transmission transistor 311 transfers the charges into the capacitor 313 and the capacitor 314, and the transmission transistor 312 transfers the charges into the capacitor 315 and the capacitor 316. The processing circuit (which is not shown in the drawings) converts the charges stored in these capacitors into a current signal or a voltage signal for output. In an embodiment, the storage capacity of the capacitor 314 is greater than the storage capacity of the capacitor 313, and the storage capacity of the capacitor 316 is greater than the storage capacity of the capacitor 315. In this way, the area occupied by the capacitor 313 and the capacitor 315 on the first substrate 301 can be further reduced, so that more pixel units can be arranged on the first substrate 301, thereby increasing the resolution and the dynamic range of the image processor.

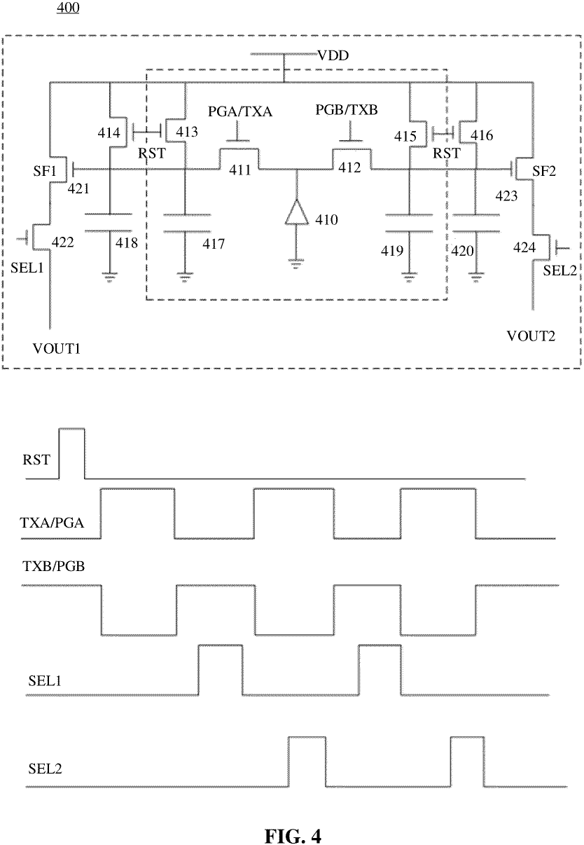

In another embodiment, the processing circuit may further include a reset device and a readout device. As an example, the photoelectric unit is a photodiode, the transmission path control portion is a transmission transistor which is also called a transmission gate, the reset device is a reset transistor, and the readout device is a source follower (SF). A workflow of an image sensor 400 provided in the present disclosure is described in detail with reference to FIG. 4.

Firstly, reset transistors 413 and 414 are turned on, i.e., the transistors 413 and 414 are applied with a high level to reset the charges on capacitors 417 and 418. The reset charges are read out, i.e., a corresponding source follower 421 and a corresponding row selection switch 422 are turned on to read out the reset current. Accordingly, reset transistors 415 and 416 are turned on, i.e., gates of the transistors 415 and 416 are applied with a high level to reset the charges on capacitors 419 and 420. The reset charges are read out, i.e. a corresponding source follower 423 and a corresponding row selection switch 424 are turned on to read out the reset current.

It should be noted that the reset transistors 413, 414, 415 and 416 may be turned on at the same time, or the transistors 413 and 414 may be turned on prior to the transistors 415 and 416.

Next, the reset transistors 413, 414, 415 and 416 are turned off, i.e., the gates of these transistors are applied with a low level. A photodiode 410 receives a light signal and converts the light signal into photogenerated electrons. Gates of a transmission gate 411 and a transmission gate 412 are respectively supplied with modulating signals, which are shown as TXA/PGA and TXB/PGB in FIG. 4, respectively, for demodulating the light signals in phases of 0° and 180°.

Exemplarily, the transmission gate 411 transmits the photogenerated electrons in the phase of 0° to the capacitors 417 and 418 for storage, and the transmission gate 412 transmits the photogenerated electrons in the phase of 180° to the capacitors 419 and 420 for storage. Optionally, the transmission gate 411 is turned on firstly, and the charges in the photodiode 410 in the phase of 0° are transferred to the capacitor 417 and the capacitor 418 through the transmission gate 411. The modulated charges in the phase of 0° are read out, i.e., a corresponding source follower 423 and a corresponding row selection switch 424 are turned on to read out the modulated current in the phase of 0°. Next, the transmission gate 412 is turned on again, and a part of the charges in the photodiode 410 are transferred to the capacitor 419 and the capacitor 420 through the transmission gate 412. The modulated charges in the phase of 180° are read out, i.e., the corresponding source follower 423 and the corresponding row selection switch 424 are turned on to read out the modulated current in the phase of 180°. These two readout currents and the currents in the two phases may be processed by a subsequent circuit (which is not shown in the drawings) to obtain distance information of the target object, i.e., depth information, and thus the 3D image of the target object is obtained.

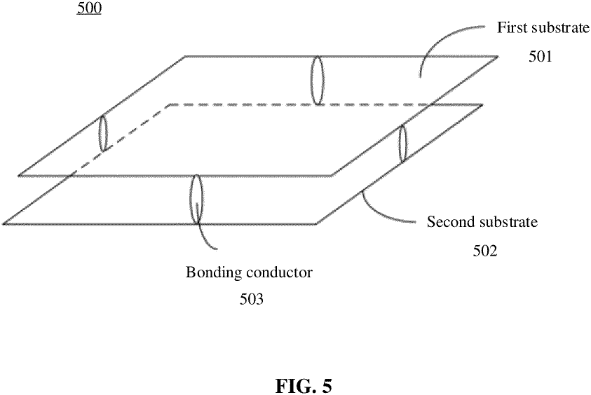

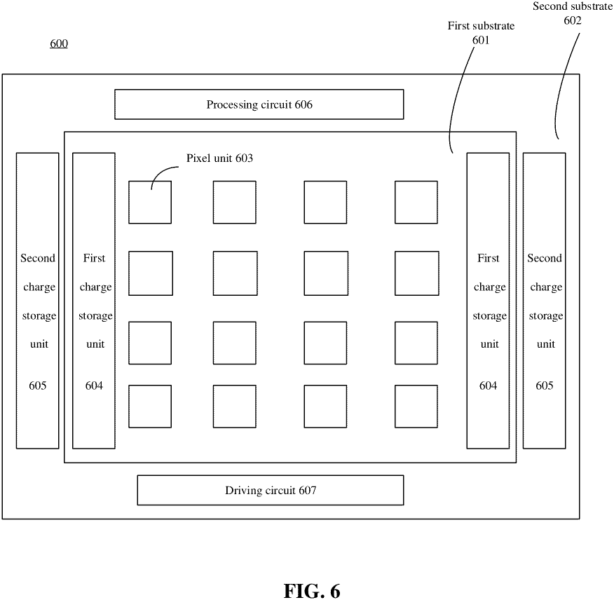

Optionally, in an image sensor 500 as shown in FIG. 5, a first substrate 501 and a second substrate 502 are connected by a bonding conductor 503. Accordingly, an electronic device is further provided in the present disclosure. The electronic device includes a light source for emitting a light signal to a target object, and an image sensor for receiving the light signal reflected from the target object and generating an electrical signal. Exemplarily, an image sensor 600 as shown in FIG. 6 includes: a first substrate 601 and a second substrate 602. The first substrate is provided with a pixel array including pixel units 603. The pixel unit 603 includes a photoelectric unit, a transmission path control portion and a first charge storage unit 604. The photoelectric unit is used to receive a light signal and generate photogenerated electrons. The transmission path control portion is used to control transmission of the photogenerated electrons. The charge storage unit is used to store the photogenerated electrons transmitted by the transmission device. The second substrate includes second charge storage units 605 and a processing circuit 606. The processing circuit is used to process the photogenerated electrons stored in the first charge storage unit and the second charge storage unit.

Optionally, the image sensor further includes a driving circuit 607 for driving the readout of the signal of the pixel circuit on the first substrate 601.

The first charge storage unit 604 and the second charge storage unit 605 are respectively arranged on the first substrate 601 and the second substrate 602. In this way, the first substrate and the second substrate together provide a unit for storing charges, avoiding the situation where the charge storage unit occupies a large amount of substrate area when being arranged on only the first substrate, which leads to a reduction in the area available for other circuits. Further, if the charge storage unit is arranged on only the second substrate, there exists the following problems. For example, the size of other components in the analog circuit is occupied, the junction capacitance is difficult to be fabricated due to being large, and the junction capacitance cannot be fully utilized. In other words, by providing the charge storage device on the two substrates, the capacity of the charge storage device can be increased, and thus the dynamic range of the image sensor can be improved.

Optionally, the storage capacity of the second charge storage unit 605 is greater than the storage capacity of the first charge storage unit 604.

Thus, the area occupied by the first charge storage unit 604 on the first substrate 601 can be further reduced, so that more pixel units can be arranged on the substrate 601, thereby improving the dynamic range of the image sensor.

Optionally, the processing circuit 606 includes a reset device and a readout device. The reset device is used to reset the charge storage unit. The readout device is used to process and read out the photogenerated electrons in the charge storage unit.

Optionally, the first substrate 601 and the second substrate 602 are distributed in a vertical direction, the first substrate 601 and the second substrate 602 are connected via a bonding conductor, and the first charge storage unit 604 and the second charge storage unit 605 are electrically connected via the bonding conductor.

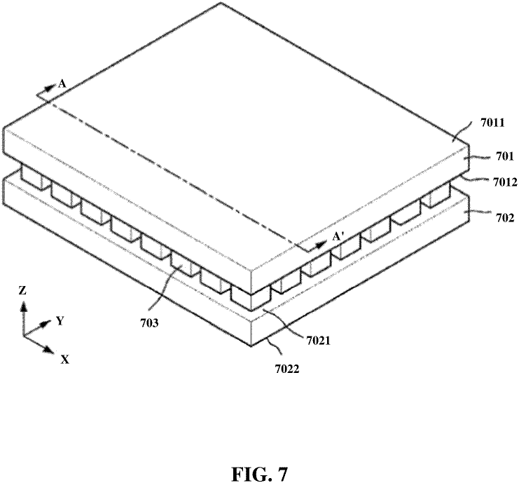

FIG. 7 is a perspective schematic view of a detection device according to an embodiment of the present disclosure, and this structural layout may be adopted in practice. FIG. 7 only shows the two substrates and a connection structure of the bonding conductor between the two substrates, a filler material may be provided for a bonding conductor 703, which is not limited herein. In FIG. 7, a state that a connection portion playing a conduction role exists between the two substrates is illustrated, which does not limit the present disclosure. The detection device includes: a first substrate 701, a second substrate 702 and the bonding conductor 703. The first substrate 701 may be arranged in a horizontal plane. The horizontal plane may be defined by a first direction X and a second direction Y. Specifically, the first direction X and the second direction Y may be orthogonal to each other. The first direction X and the second direction Y may be directions that define the width and the length of the first substrate 701. The first substrate 701 may be arranged in a plane defined by the first direction X and the second direction Y.

A third direction Z may be a direction orthogonal to both of the first direction X and the second direction Y. Thus, the first direction X, the second direction Y and the third direction Z may be orthogonal to each other. If the plane defined by the first direction X and the second direction Y is a horizontal plane, the third direction Z may be defined as a vertical direction.

The first substrate 701 may include a first top surface 7011 and a first bottom surface 7012. The first top surface 7011 and the first bottom surface 7012 of the first substrate 701 may be surfaces of the first substrate 701 that are opposite each other in the third direction Z.

The second substrate 702 may be spaced apart from the first substrate 702 in the third direction Z. That is, the second substrate 702 may be arranged below the first substrate 701. The second substrate 702 may correspond to the first substrate 701. The structure in the drawing is exemplified herein. The structure in the drawing may be divided into an upstream and a downstream according to an incidence direction of return light. The first substrate 701 is provided at an upstream position in the propagation direction of the return light, and the second substrate 702 is provided at a downstream position in the propagation direction of the return light. Specifically, the second substrate 702 may be completely overlapped with the first substrate 701 in the third direction Z or the propagation direction of the return light. The first substrate 701 and the second substrate 702 may share the same horizontal cross-portion and may completely overlap each other, which is not limited herein.

The second substrate 702 may include a second top surface 7021 and a second bottom surface 7022. The second top surface 7021 and the second bottom surface 7022 of the second substrate 702 may be surfaces of the second substrate 702 that are opposite each other in the third direction Z or in the propagation direction of the return light.

The bonding conductor 703 may be arranged between the first substrate 701 and the second substrate 702. The bonding conductor 703 may be arranged to contact the first bottom surface 7012 of the first substrate 701 and the second top surface 7021 of the second substrate 702. That is, the bonding conductor 703 may be arranged between the first substrate 701 and the second substrate 702 in the third direction Z.

The first substrate 701 and the second substrate 702 may be electrically connected by the bonding conductor 703. The bonding conductor 703 may include a conductor. The bonding conductor 703 may be formed by a material, for example, a metal such as Cu. The bonding conductor may be implemented by an intra-pixel Bounding process without complicated perforations and the like, ensuring the reliability of the manufacturing process, which is not limited in the present disclosure.

Multiple bonding conductors 703 may be provided. The multiple bonding conductors 703 may be aligned to form an array of connecting portions.

In an implementation, the first substrate 701 may be processed by an N-type doping process to have an N-type epitaxial layer. In this case, the photoelectric unit of the pixel is arranged on the first substrate 701, ensuring the fast absorption for the return light. Furthermore, by doping the N-type material such as boron and other pentavalent elements or ions, a fully depleted type region is formed in the first substrate 701, to ensure the conversion efficiency of the photoelectric unit in the first substrate 701, and further achieve the maximum conversion. In addition, the first substrate 701 is set to have a wiring width of 1 nm, which ensures that the photoelectric unit can obtain a larger area to further improve the light absorption effect of the photoelectric unit. Furthermore, the first substrate 701 is made of a SiGe material, to ensure the reliability of each part in the first substrate 701. The first substrate 701 is designed in accordance with the optimal absorption depth of light. For example, for the infrared laser having more distance measurement applications, the thickness of the epitaxial layer in the first substrate 701 is designed to be more than 20 µm, so that the entire first substrate 701 can meet requirements for the efficient and reliable operation of the detection pixel with a high integration level and a small size.

The second substrate 702 may be processed by a P-type doping process, for example, by the addition of phosphorus and other trivalent elements or ions, to have a P-type epitaxial layer. In this way, more photoelectric transistors for transmission, modulation, following, reset, or the like can be directly formed as an NMOS type, ensuring the high efficiency of the entire process production. In addition, the second substrate 702 is set to have a wiring width of 5 nm, which ensures the signal transmission efficiency and further ensures the reliability of the production process to minimize the possibility of device failure caused by broken wires. Furthermore, the second substrate 702 is made of a silicon material, to ensure the optimization of the production cost and ensure the simplicity of the production. The thickness of the second substrate 702 is designed in accordance with the strength requirements of the entire device. The thickness of the second substrate 702 is greater than the thickness of the first substrate 701, so that the device can work efficiently and reliably with a higher integration level and a small size.

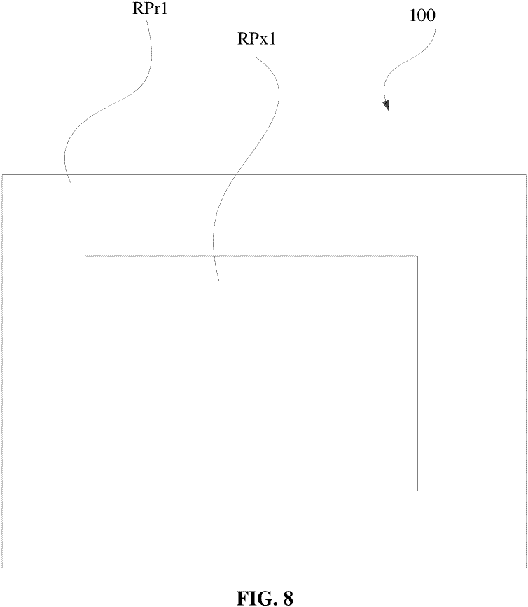

FIG. 8 is a schematic diagram showing a first substrate of a detection device according to an embodiment of the present disclosure. As shown in FIG. 8, with reference to FIG. 8, the first substrate may have a first pixel region RPx1 and a first peripheral region RPr1. The first pixel region RPx1 may be a region in which pixels of a detection sensor according to some example embodiments of the present disclosure are arranged. In the plan view, the first pixel region RPx1 may be surrounded by the first peripheral region RPr1. The first pixel region RPx1 may be a region where the light is received from outside. The first peripheral region RPr1 may surround the first pixel region RPx1. That is, the first peripheral region RPr1 may be a peripheral region of the first pixel region RPx1. In the first peripheral region RPr1, a circuit for processing the signal generated in the first pixel region RPx1 may be arranged. Similarly, the second substrate may be the same as the first substrate. The peripheral region RPr1 outside the pixel region RPx1 of the first substrate 100 may be provided with, for example, black pixels (or called shading pixels). These pixels are not used to receive light signals and may be provided with the same structure as the pixel region, so that a reference voltage, a ramp voltage, or the like can be generated, which is not described in detail herein.

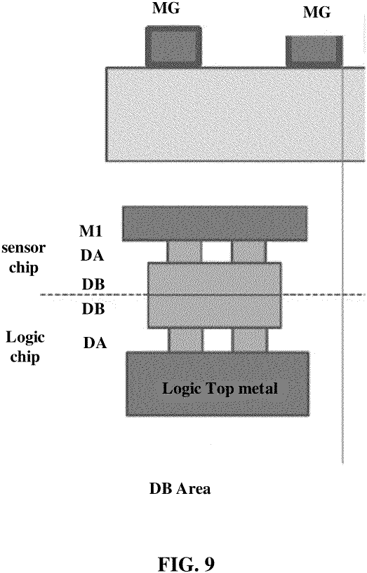

FIG. 9 is a schematic sectional diagram taken along a line A-A′ in FIG. 1 according to an embodiment of the present disclosure. A reference numeral DA indicates a drilled hole of the first pixel portion and the second pixel portion, and a reference numeral DB indicates a bonding conductor 703 connecting the first pixel portion and the second pixel portion. The bonding conductor 703 may be metal, and such a bonding process may be called an intra-pixel Bounding process. In order to ensure the signal transmission reliability and the transmission is not affected by the bonding region, each two adjacent bonding conductors 703 must have a certain spacing in a case that the number of bonding conductors 703 in the pixel is greater than or equal to 2, which further ensures the processing reliability in the production and improves the production efficiency. Centers of any two bonding conductors 703 are required to have a spacing ranging from 2 µm to 6 µm, which is not limited in the present disclosure.

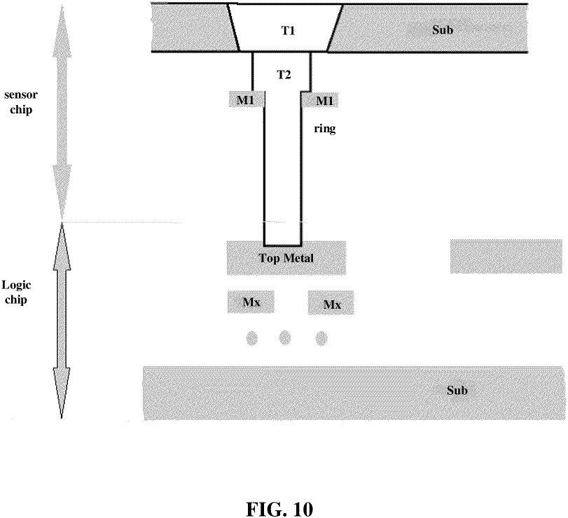

FIG. 10 shows that a circuit driving portion on the second substrate according to the embodiment of the present disclosure may generate a transmission path connection signal and transmit the transmission path connection signal to the transmission path of the first substrate by at least one conducting portion different from the conductor bonding portion connecting the upstream pixel to the downstream pixel. The conducting portion is at least partially contained in a through-hole formed by the TSV process, by which the conducting portion is formed in the first substrate to ensure the reliability of the signal transmission. The circuit driving portion may be provided on the second substrate in the propagation direction of the return light in the first peripheral region RPr1 of the first substrate. The electrical connection between the driving circuit and the transmission path in FIG. 6 may be similar to the structure in FIG. 10, which is not limited herein.

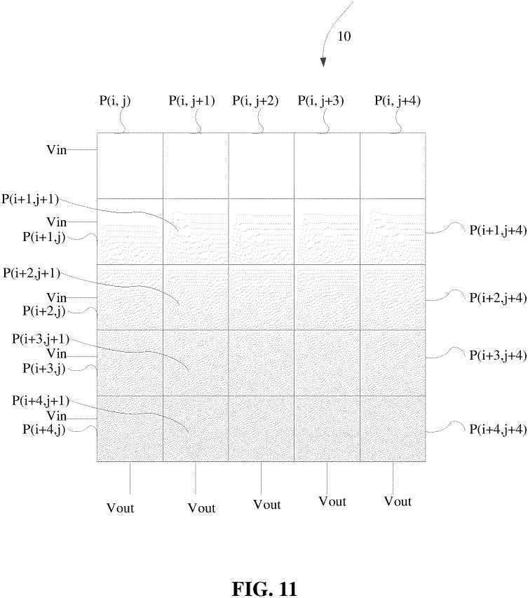

FIG. 11 is a schematic diagram showing a layout of a pixel array according to an embodiment of the present disclosure. As shown in FIG. 11, a pixel array 10 includes five rows and five columns of pixels as an example, which is not limited in the present disclosure. That is, the number of rows of pixels and the number of columns of pixels in the pixel array 10 each may vary.

The planar arrangement of the pixel array 10 may be limited to a given horizontal region, as shown in FIG. 11, independent of the division of a pixel P(i, j) into a first pixel portion and a second pixel portion. The pixel P(i, j) may be rectangular in shape, which is not limited in the present disclosure. The pixel P(i, j) may be arranged to adjoin other pixels on a side thereof.

The pixel P(i, j) may receive an input signal Vin and may generate an output signal Vout. The input signal Vin may be supplied to the pixel array 10 in rows of the pixel array 10. The output signal Vout may be generated in columns of the pixel array 10.

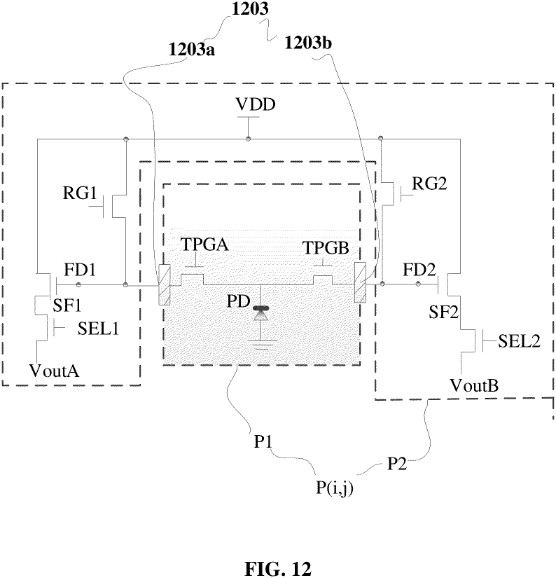

FIG. 12 is a schematic diagram showing an equivalent circuit of an example pixel of a pixel array according to an embodiment of the present disclosure. As shown in FIG. 6, the pixel P (i, j) may include a first pixel portion P1, a second pixel portion P2, and a pixel bonding conductor 1203. The first pixel portion P1 may be formed in a first pixel region Px1 of the first substrate. The second pixel portion P2 may be formed in a second pixel region of the second substrate. As elements of the pixel P (i, j), the first pixel portion P1 and the second pixel portion P2 are divided between the two substrates, so that the horizontal area of the pixel P (i, j) can be minimized.

The bonding conductor 1203 may electrically connect the first pixel portion P1 and the second pixel portion P2. The bonding conductor 1203 may include a first connecting portion 1203a and a second connecting portion 1203b. Alternatively, the pixel P (i, j) may be provided with two pixel bonding portions 1203, since the pixel P (i, j) is a 2-tap pixel with two gratings.

If the pixel P (i, j) is a 3-tap pixel with three gratings or a 4-tap pixel with four gratings, the pixel P (i, j) may be provided with three or four pixel bonding portions 1203. That is, the number of gratings provided in the pixel P (i, j) may be the same as the number of pixel connecting portions 1203 provided in the pixel P (i, j).

The first pixel portion P1 may include a photoelectric conversion unit PD, and two signal transmission paths connected to the photoelectric conversion unit PD. The two transmission paths include a first modulation transfer element TPGA and a modulation transfer element TPGB. The second pixel portion P2 may include two charge storage units FD1 and FD2 respectively corresponding to the two transmission paths. The second pixel portion further includes a first reset transistor RG1, a second reset transistor RG2, a first source follower SF1, a second source follower SF2, a first selection transistor SEL1 and/or a second selection transistor SEL2.

The photoelectric element PD may be an element that converts light applied thereto into electrical charges.

Specifically, the photoelectric element PD may sense the light. The photoelectric element PD may generate electron-hole pairs (EHP) based on the sensed light.

The first modulation transfer element TPGA is connected to a first floating diffusion region FD1 (first storage unit). The second modulation transfer element TPGB is connected to a second floating diffusion region FD2 (second storage unit). The two storage units may be MOS-type capacitors molded on the second substrate.

The first floating diffusion region FD1 is connected to the first source follower SF1. A power supply voltage VDD is applied to the first source follower SF1. The first selection transistor SEL1 is connected to the first source follower SF1. A source voltage of the first source follower SF1 is determined by a voltage of the first floating diffusion region FD1. The voltage of the first floating diffusion region FD1 is determined by the amount of electrons transferred from the first modulation transfer element TPGA.

A row control signal is provided to the first selection transistor SEL1. The first source follower SF1 is connected to the selection transistor SEL1 for a first source. The output line of the pixel array 10 is connected to the first selection transistor SEL1.

The power supply voltage VDD is applied to the first reset transistor RG1. The first floating diffusion region FD1 is connected to the first reset transistor RG1. The detection of the pixel information is performed based on the voltage of the first floating diffusion region FD1. The first reset transistor RG1 is activated with a first reset signal, and the first reset transistor RG1 resets the voltage of the first floating diffusion region FD1 to the power supply voltage VDD.

When the photoelectric unit PD senses the light, the second floating diffusion region FD2 is connected to the second source follower SF2, the power supply voltage VDD is applied to the second source follower SF2, and the second selection transistor SEL2 is connected to the second source follower SF2. The source voltage of the second source follower SF2 is determined by the voltage of the second floating diffusion region FD2. The voltage of the second floating diffusion region FD2 is determined by the amount of electrons transferred from the first modulation transfer element TPGA.

The row control signal is provided to the second selection transistor SEL2. The second source follower SF2 is connected to the selection transistor SEL2 for a second source. The output line of the pixel array 10 is connected to the second selection transistor SEL2.

The power supply voltage VDD is applied to the second reset transistor RG2. The second floating diffusion region FD2 is connected to the second reset transistor RG2. The detection of the pixel information is performed based on the voltage of the second floating diffusion region FD2. The second reset transistor RG2 is activated by a second reset signal, and the second reset transistor RG2 resets the voltage of the first floating diffusion region FD2 to the power supply voltage VDD. In addition, the first substrate is further provided with a MOS-type capacitor having more storage functions between the modulation transfer transistor and the floating diffusion node, without limiting the specific implementation herein.

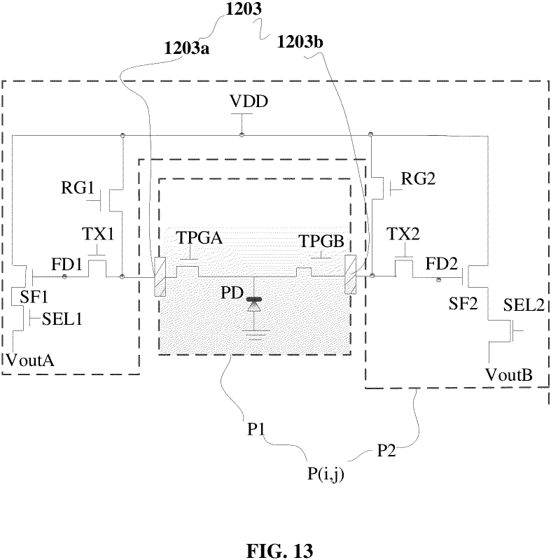

FIG. 13 is a schematic diagram showing an equivalent circuit of an example pixel of a pixel array according to another embodiment of the present disclosure. The functions of the components similar to those in FIG. 12 are not further described. The solution shown in FIG. 13 differs from FIG. 12 in that, a demodulation transistor is provided on the first substrate to receive the emitted light with different phases or modulated by pseudo-random coding to ensure the reliability of the system, and the transfer transistor is provided on the second substrate. The operation principles of the remaining components are similar to FIG. 6. More charge storage units may be provided on the first substrate under this structure, which is not limited in the present disclosure.

Preferred embodiments of the present disclosure are given in the above description, and are not intended to limit the present disclosure. For those skilled in the art, the present disclosure may have various modifications and changes. Any modifications, equivalents and improvements made in the spirit and principle of the present disclosure should be included in the protection scope of the present disclosure. It should be noted that similar numerals and letters refer to similar items in the following drawings. Therefore, if an item is defined in a drawing, the item is not required to be further defined and explained in subsequent drawings. Preferred embodiments of the present disclosure are given in the above description, and are not intended to limit the present disclosure. For those skilled in the art, the present disclosure may have various modifications and changes. Any modifications, equivalents and improvements made in the spirit and principle of the present disclosure should be included in the protection scope of the present disclosure.

1. An image sensor, comprising:
a first substrate, comprising at least a photoelectric unit for photoelectric conversion, wherein N signal transmission paths are connected to the photoelectric unit, N is greater than or equal to 1; and
a second substrate, comprising N second charge storage units respectively corresponding to the N transmission paths, wherein the transmission paths are used to: receive control signals, electrically connect the photoelectric unit to the second charge storage units, and transfer at least part of photogenerated electrons generated in the photoelectric unit to the second charge storage units.

2. The image sensor according to claim 1, wherein
the first substrate further comprises N first charge storage units respectively corresponding to the N signal transmission paths, the transmission paths are used to: receive control signals and transfer at least part of the photogenerated electrons generated in the photoelectric unit to the first charge storage units and the second charge storage units; and
the second substrate further comprises a processing circuit configured to process the photogenerated electrons stored in the first charge storage units and the second charge units.

3. The image sensor according to claim 1, wherein
the first substrate further comprises N transmission path control portions connected to the photoelectric unit to form an upstream pixel region; and
the second substrate further comprises a downstream pixel region corresponding to the upstream pixel region, wherein
the upstream pixel is directly or indirectly connected to the N charge storage units of the downstream pixel via N bonding conductors respectively corresponding to the N signal transmission paths, and the photogenerated electrons generated by the photoelectric units are at least partially transferred to the charge storage units.

4. The image sensor according to claim 1, wherein the number N of the signal transmission paths is two, the first substrate is connected to the second substrate by two bonding conductors, and the two charge storage units receive at least part of the photogenerated charges generated by the photoelectric unit via the two bonding conductors.

5. The image sensor according to claim 1, wherein the first substrate and the second substrate have different thicknesses.

6. The image sensor according to claim 1, wherein the first substrate and the second substrate are made of different materials and/or by different processes.

7. The image sensor according to claim 4, wherein the first transmission paths and the second transmission paths are formed by transistor structures and are electrically connectable to the first charge storage units and the second storage units in a time division manner so that the photogenerated electrons generated by the photoelectric unit are at least partially transferred to the first charge storage units or the second charge storage units.

8. The image sensor according to claim 3, wherein in a case that the number N of the transmission paths is greater than or equal to two, a space between centers of any two of the bonding conductors ranges from 2 µm to 6 µm.

9. The image sensor according to claim 3, wherein the second substrate further comprises N transfer transistors respectively corresponding to the N signal transmission paths, and the transfer transistors are arranged between the bonding conductors and the charge storage units.

10. The image sensor according to claim 3, wherein the second substrate further comprises N source followers, and the N source followers are respectively connected to the N charge storage units.

11. The image sensor according to claim 9, wherein the second substrate further comprises N row selection transistors respectively connected to the N source followers.

12. The image sensor according to claim 3, further comprising:
a pixel array in which a plurality of pixels are arranged in rows in a first direction and in columns in a second direction, wherein each of the plurality of pixels is formed by connecting the upstream pixel region to the downstream pixel region via a plurality of the bonding conductors.

13. The image sensor according to claim 3, wherein
a first pixel portion comprising at least the photoelectric unit of the upstream pixel region is provided on the first substrate; and
the second substrate comprises a second pixel portion corresponding to the first pixel portion and is spaced apart from the first substrate in a vertical direction, and the second pixel portion comprises at least the second charge storage units.

14. The image sensor according to claim 13, wherein a horizontal section of the first pixel portion and a horizontal section of the second pixel portion are rectangular and overlap each other in the vertical direction.

15. The image sensor according to claim 2, wherein a storage capacity of the second charge storage unit is greater than a storage capacity of the first charge storage unit.

16. The image sensor according to claim 2, wherein the processing circuit comprises:
a reset device configured to reset the second charge storage unit; and
a readout device configured to process and read out the photogenerated electrons in the charge storage unit.

17. The image sensor according to claim 2, wherein the number N of the signal transmission paths is two, and the first substrate comprises two first charge storage units corresponding to the number of the signal transmission paths.

18. A detection system for performing detection by the image sensor according to claim 1, the detection system comprising:
a light source configured to emit a light signal to a target object;
an image sensor configured to receive the light signal reflected from the target object and generate an electrical signal, wherein the image sensor comprises:
a first substrate, comprising at least a photoelectric unit for photoelectric conversion, wherein N signal transmission paths are connected to the photoelectric unit, N is greater than or equal to 1; and
a second substrate, comprising N second charge storage units respectively corresponding to the N transmission paths, wherein the transmission paths are used to: receive control signals, electrically connect the photoelectric unit to the second charge storage units, and transfer at least part of photogenerated electrons generated in the photoelectric unit to the second charge storage units.

19. The detection system according to claim 18, wherein
the first substrate further comprises N first charge storage units respectively corresponding to the N signal transmission paths, the transmission paths are used to: receive control signals and transfer at least part of the photogenerated electrons generated in the photoelectric unit to the first charge storage units and the second charge storage units; and
the second substrate further comprises a processing circuit configured to process the photogenerated electrons stored in the first charge storage units and the second charge units.

20. The detection system according to claim 19, wherein a storage capacity of the second charge storage unit is greater than a storage capacity of the first charge storage unit.
